(19) United States
(12) Patent Application Publication
(10) Pub. No.: US 2010/0037577 A1
(43) Pub. Date: Feb. 18, 2010

(54) Crop Anti-Wrapping Method and Apparatus

(76) Inventors: Philip J. Egging, Reasnor, IA (US); Eric T. Woodford, Redwood Falls, MN (US); Thomas M. Duenwald, Pella, IA (US); Lisle J. Dunham, Grinnell, IA (US); Calvin D. Meinders, Pella, IA (US)

Correspondence Address: STURM & FIX LLP, 206 SIXTH AVENUE, SUITE 1213, DES MOINES, IA, 50309-4076, US

(21) Appl. No.: 12/193,447

(22) Filed: Aug. 18, 2008

(51) Int. Cl. A01D 82/00; H01L 21/677; B23P 13/04

(52) U.S. Cl. 56/1; 414/800; 29/558

(57) ABSTRACT

An oversleeve for preventing crop material from wrapping around an agricultural implement shaft. The oversleeve is disposed over the implement shaft and affixed to a stripper pan so it does not rotate with the shaft. The oversleeve is preferably made of a polymer composite material. Removal of dirt between the shaft and oversleeve is effected by a helical groove arranged so the dirt is driven to the ends of the oversleeve.

### CROSS REFERENCE TO RELATED APPLICATIONS

Not applicable.

### BACKGROUND OF THE INVENTION

1. Field of the Invention

The present invention relates generally to an improvement for an agricultural implement. More particularly, the present invention relates to a device to minimize or eliminate the wrapping of crop or crop residue on an implement shaft.

2. Background Art

Some agricultural implements, notably balers, encounter long fragments of crop or crop residue that may wrap around turning shafts. Crop wrapping has long been a recognized problem. Existing Mowers employ “hats” placed around driveshafts to deflect crop material from the shaft. Balers have bearing protectors. Implement bearing seals have hard covers to prevent seal damage.

The rotor of a modern baler is designed to help move forage material into the baler. The rotor commonly comprises a shaft and a plurality of rotor plates spaced along the shaft. The location and function of the rotor shaft is such that crop wrapping is common and problematic. Wrapped crop material inhibits the function of the rotor while adding to the friction of rotation.

There is, therefore, a need for a method and apparatus for preventing wrapping of crop material on rotating shafts in agricultural implements.

### BRIEF SUMMARY OF THE INVENTION

An object of the present invention is to provide an apparatus for resisting the wrapping of crop material around a rotating shaft.

On a baler rotor shaft are mounted a plurality of rotor plates, spaced evenly and rigidly affixed to the rotor shaft—so the rotor plates rotate with the rotor shaft. To protect the rotor shaft between the rotor plates from crop material wrapping, oversleeves are provided over the rotor shaft between the rotor plates. Each oversleeve comprises a sheet of composite material wrapped in a teardrop shape over the rotor shaft. The oversleeve is kept from turning with the rotor shaft by an attachment to a pan rearward of the rotor shaft.

An additional object is to provide an effective method for the elimination of dirt from between the rotating shaft and the oversleeves used in the anti-wrapping device. A shallow helical groove is machined on the outer surface of the rotor shaft. The helical groove wraps left beginning at the center of the space between adjacent rotor plates to one end of the oversleeve, and right from the center of the same space to the other end of the oversleeve. The direction of the helix serves to collect dirt, then drive the dirt outboard from the rotor shaft and oversleeve interface.

The stripper pan to which the oversleeves are affixed may provide an additional advantage. When configured with a rod windguard, the aft leg of the rod windguard rods may be passed through an elongated slot in the pan segment. This allows the rod windguard to function independently of the rotor assembly—that is, not affixed to the rotor. Hence, the rod windguard is permitted to move upwardly with increased crop infeed, and downwardly as crop thins out.

Other objects, advantages and novel features of the present invention will become apparent from the following detailed description of the invention when considered in conjunction with the accompanying drawings.

### BRIEF DESCRIPTION OF THE DRAWINGS

FIG. 1 is a perspective view of a baler rotor assembly;

FIG. 2a is a detail of the baler rotor assembly;

FIG. 2b is a detail of the baler rotor assembly with the rod windguard removed for clarity;

FIG. 3 is a first perspective view of a large round baler;

FIG. 4 is a second perspective view of the large round baler;

FIG. 5 is a first side elevation view of the baler rotor assembly;

FIG. 6 is a second side elevation view of the baler rotor assembly;

FIG. 7 is a first side elevation view of the large round baler;

FIG. 8 is a second side elevation view of the large round baler;

FIG. 9 is a perspective view of a baler rod windguard;

FIG. 10 is a side elevation view of a shaft having two helical grooves formed therein;

FIG. 11 is a phantom view of an anti-wrap oversleeve including helical grooves formed on its inner surface;

FIG. 12 is a cutaway view of the anti-wrap oversleeve including helical grooves formed on its inner surface; and

FIG. 13 is a perspective view of the anti-wrap oversleeve including helical grooves formed on its inner surface.

### DETAILED DESCRIPTION OF THE INVENTION

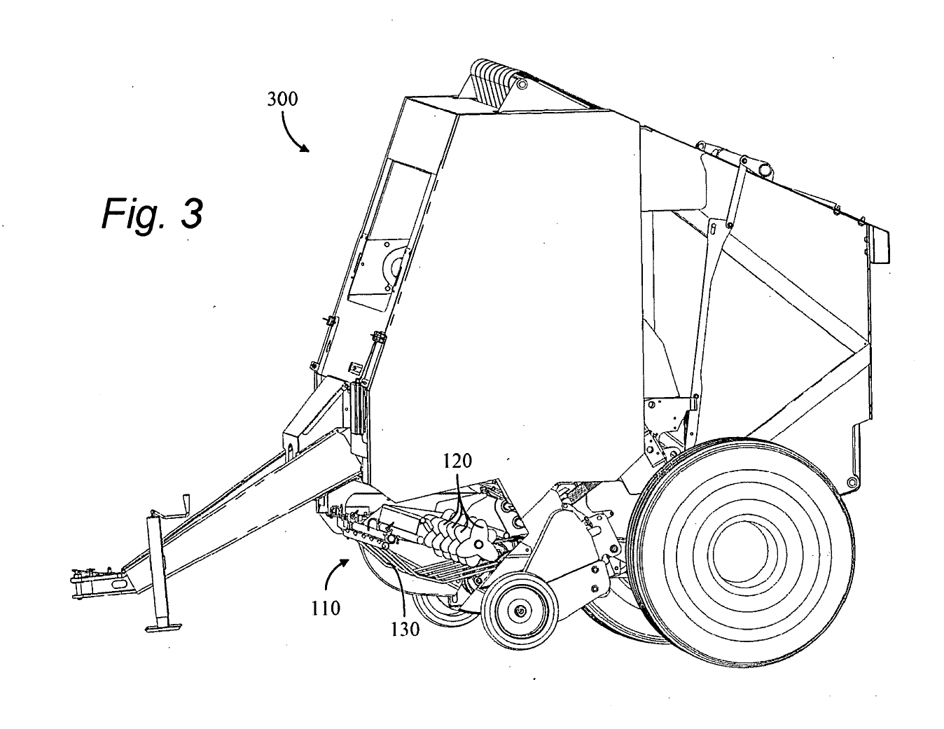

Referring now to the drawings wherein like reference numerals correspond to the same or similar parts throughout the drawings, the present invention is shown as part of a large round baler 200 in FIGS. 3, 4, 7, and 8. The application of this invention is not limited to a large round baler, however.

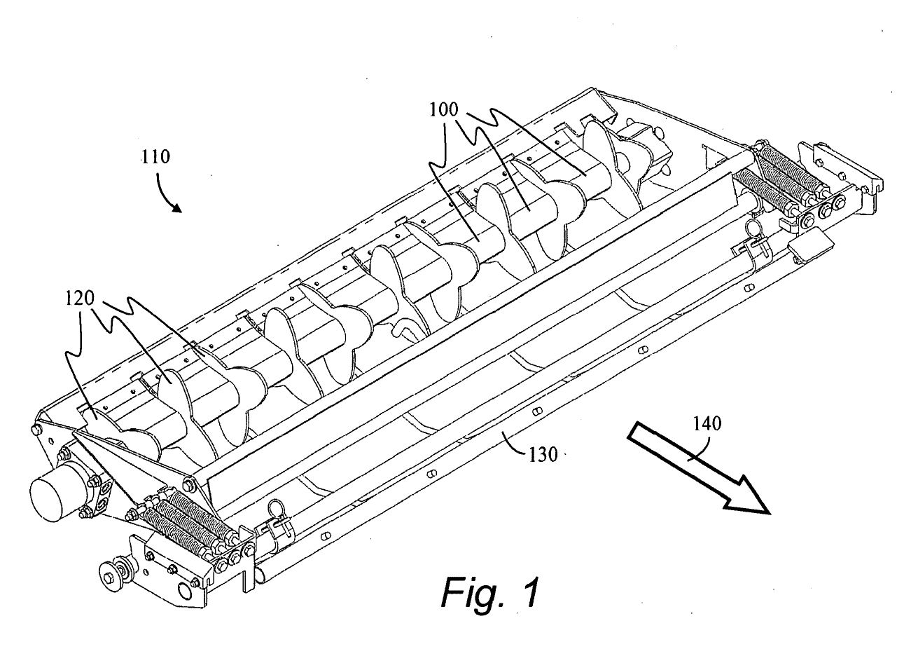

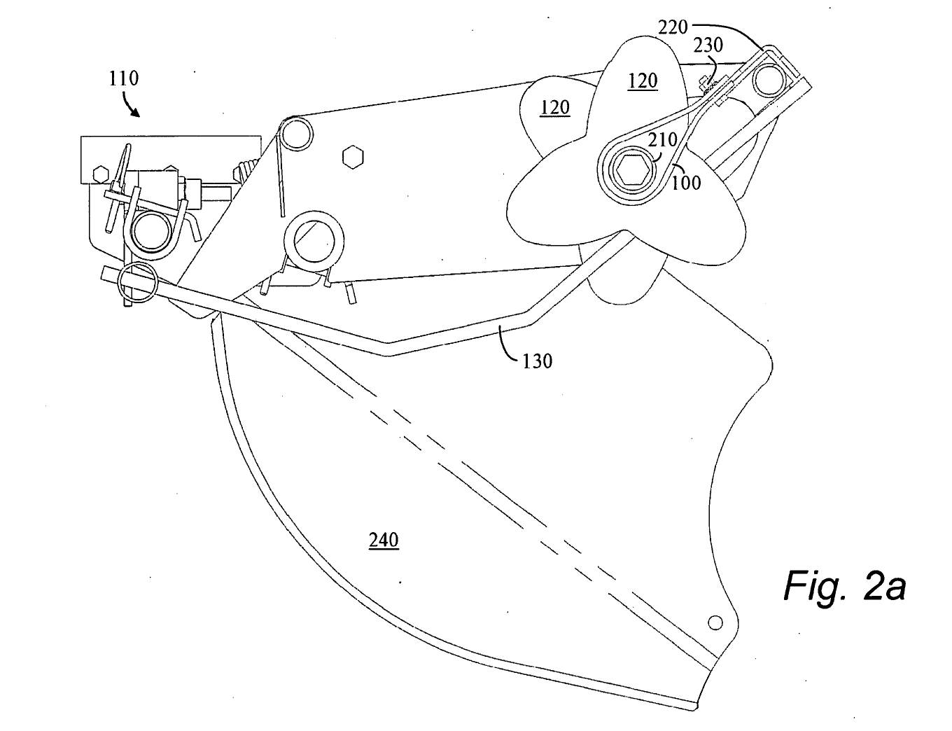

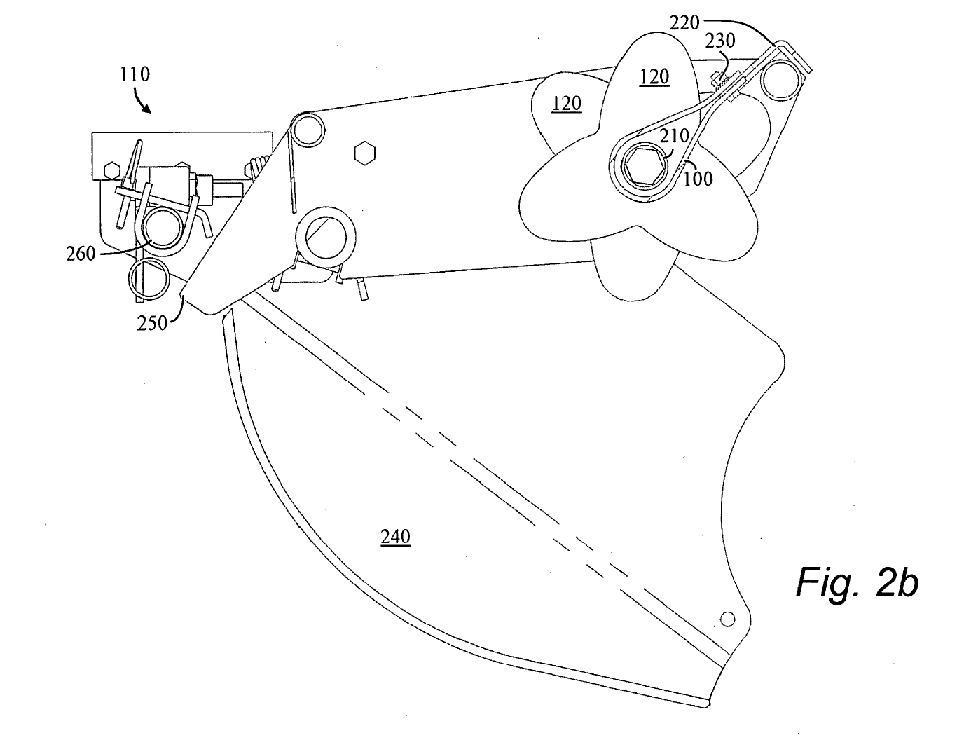

Referring to FIG. 1, a rotor assembly 110 is illustrated comprising a plurality of rotor plates 120 (all rotor plates are not numbered) with anti-wrap oversleeves 100 disposed between all the rotor plates 120, and a rod windguard 130. A rotor shaft 210, upon which the rotor plates are affixed, is not seen in FIG. 1, but may be viewed in FIG. 2. The forward direction 140 is shown in FIGS. 1, 7, and 8, and is defined for the purposes of this document, including the claims, as the usual operating direction of the implement, in this case, a large round baler 300. Likewise, the front of the implement 300 is the leading portion of the implement 300 when traveling in the forward direction. The rear of the implement is opposite the front.

Another view of one of the anti-wrap oversleeves 100 is shown in FIG. 2a. The rotor shaft 210 may also be a spacer sleeve disposed over and concentric with the rotor shaft 210; the spacer sleeves being for the purpose of spacing the rotor plates 120 on the rotor shaft 210. Either way, the anti-wrap oversleeves 100 are disposed over the rotor shaft 210 or spacer sleeves, and affixed to a stripper pan 220, preferably by bolting with the bolt assembly 230, comprising a bolt, a nut, and a lock washer. However, the present invention is not limited to any particular fastener system 230: alternatives comprise rivets, welding, brazing, and adhesive.

The rotor, comprising the rotor plates 120 and the rotor shaft 210 may be hydraulically driven, or it may driven by the flow of crop material over or under the rotor.

The anti-wrap oversleeves 100 are preferably fabricated from polymeric material, and further preferable, a composite. By using a polymer, any friction occurring due to the relative motion between the rotor shaft 210 and the anti wrap oversleeves 100 will wear on the easily replaceable anti-wrap oversleeves 100. This invention, however, is not limited to a particular material used for the anti-wrap oversleeves 100.

In FIG. 2b, the rod windguard 130 has been removed for clarity. As the rotor assembly is rotated downward, a point 250 gets closer to the bottom of a tube 260. When the point 250 contacts the bottom of the tube 260, rotation ceases. In the preferred embodiment, as the rotor assembly rotates upward, the point 250 contacts the bottom of a plate on the baler frame to limit upward rotation. In alternate embodiments, this plate may be mounted on the non-rotating portion of the windguard 130, or there could be a point similar to 250 on the opposite side of the tube 260 to contact the top of the tube 260 to limit rotation.

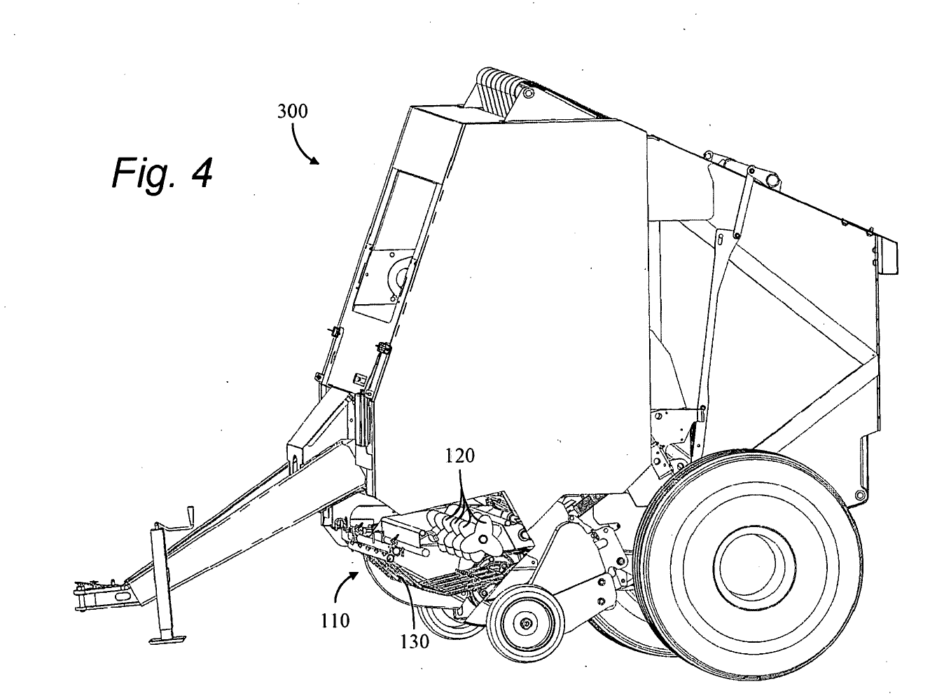

The rotor assembly 110 is shown installed on a large round baler 300 in FIGS. 3 and 4. The rotor, comprising the rotor plates 120 and the rotor shaft 210 (not shown in FIGS. 3 and 4), is shown in a lowered position in FIG. 3, whereas the rotor is shown in a raised position in FIG. 4.

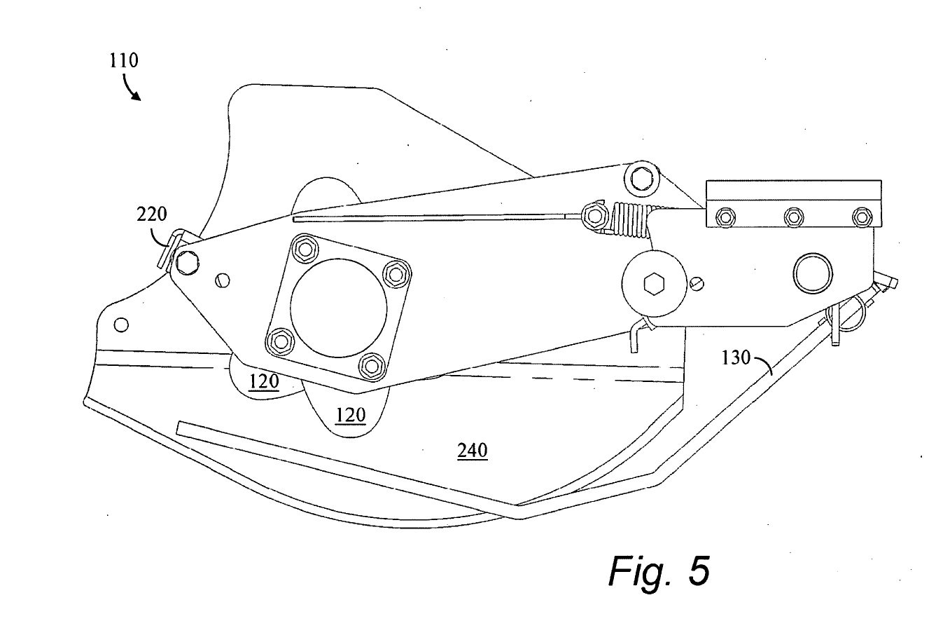

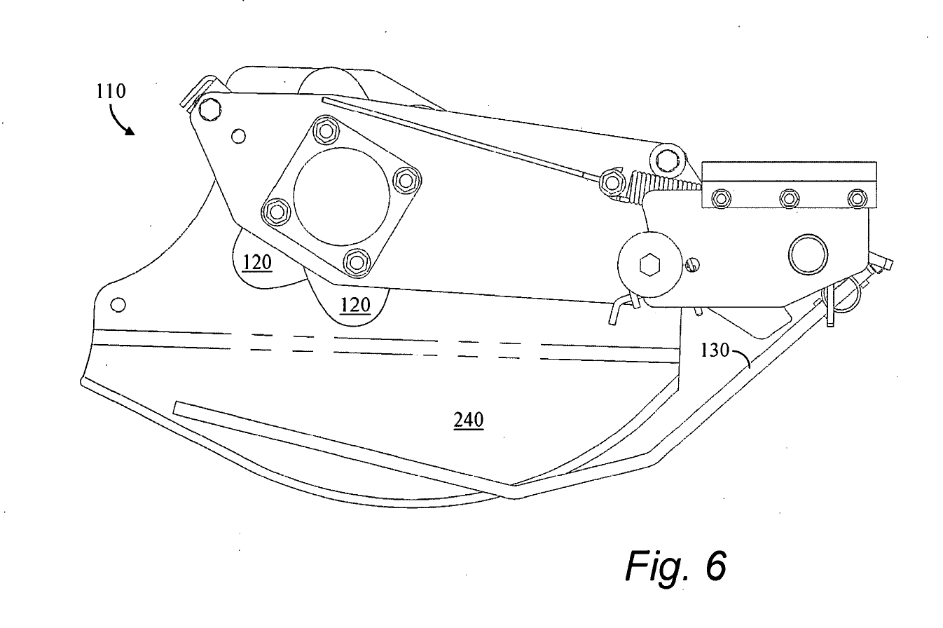

In FIGS. 5 and 6, detail views of the rotor assembly 110 are shown corresponding to FIGS. 3 and 4, respectively. In FIG. 5, the rotor, comprising the rotor plates 120 and the rotor shaft 210 is shown in a lowered position. In FIG. 6, the rotor is shown in a raised position. Comparing FIG. 5 to FIG. 6, note that the stripper pan 220 is raised and lowered simultaneously with the rotor shaft 210. Hence, the anti-wrap oversleeves 100 remain disposed in the same orientation relative to the rotor shaft 210 irrespective of position of the rotor.

Crop fins 240 are disposed at both ends of the rotor. Only one crop fin 240 is shown in FIGS. 2, 5, and 6. The crop fins 240 are intended to help guide crop material into the rotor assembly 110. The crop fins 240 can also function to move the rotor assembly 110 fore and aft.

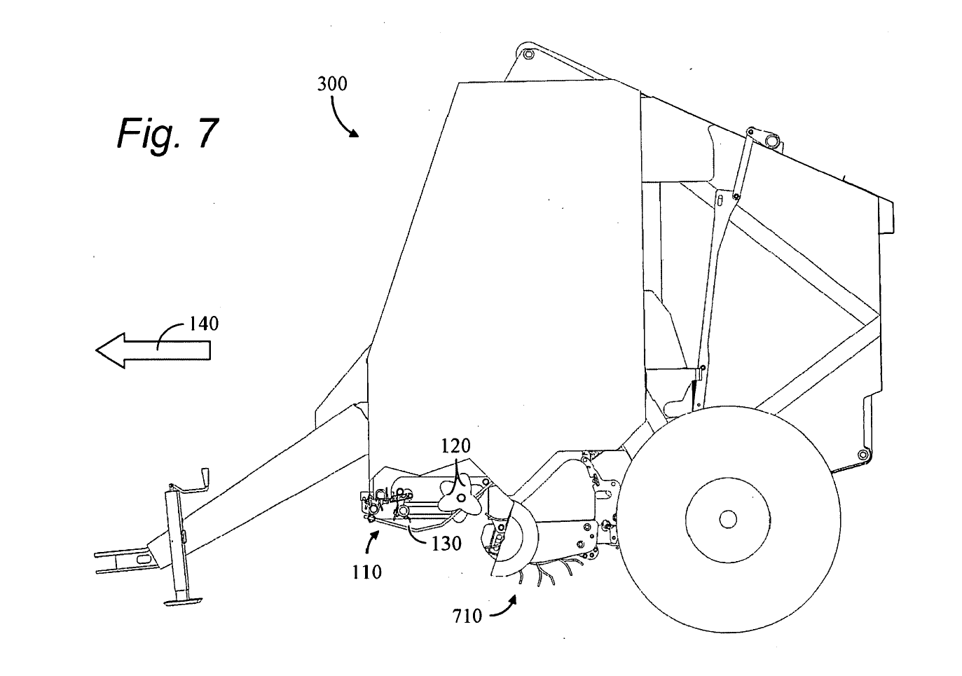

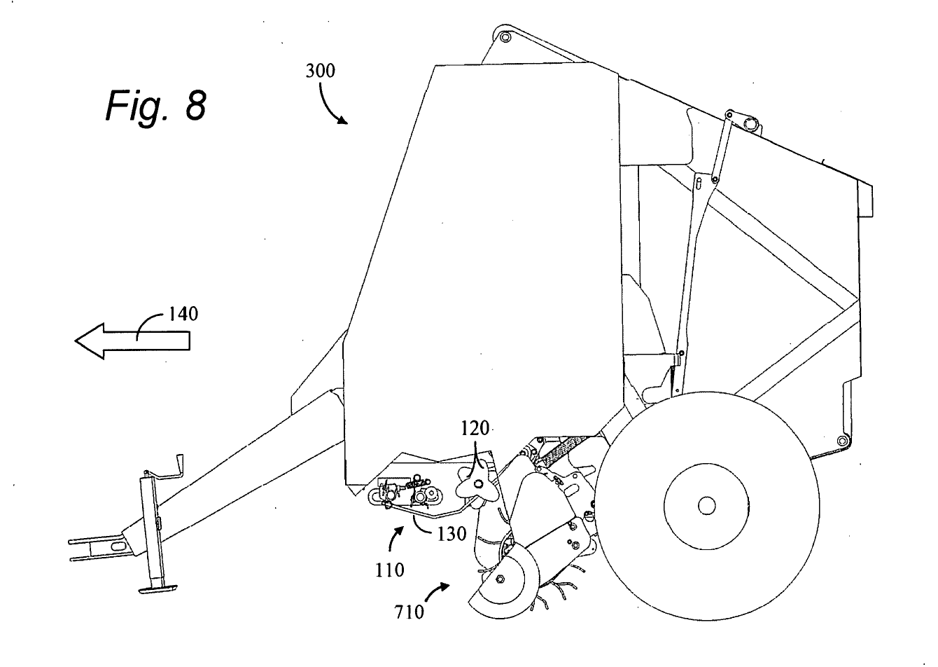

The rotor assembly 110 is permitted to move fore and aft, as shown in FIGS. 7 and 8. The rotor assembly 110 is placed in the forward position, when the pickup header 710 is in a raised position as shown in FIG. 7. When the pickup header 710 is in a lowered position, as shown in FIG. 8, the rotor assembly 110 is placed in the aft or rearward position.

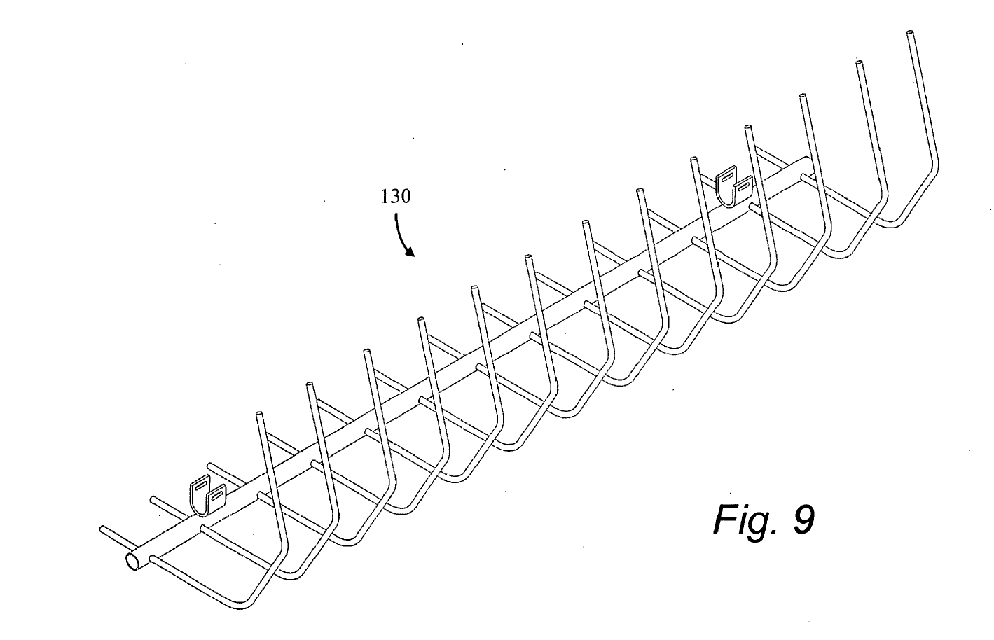

A view of the rod windguard 130 alone is shown in FIG. 9. The stripper pan 220 is preferably configured with the rod windguard 130. The rear portion of the individual rods of the rod windguard 130 pass through an elongated aperture in the stripper pan 220. The rods, then, function independently of the rotor, that is, not fixed to the rotor. The rod windguard 130 is, therefore, permitted to rise with increased crop infeed, then drop as the crop thins out. The rear portion of the rods of the rod windguard 130 and/or the stripper teardrop-shaped anti-wrap oversleeves 100 serve to guide the crop as well. In an additional embodiment, the rod windguard 130 pivots only upon moving the rotor slide frame. The rods of the rod windguard 130 are not engaged with the stripper pan 220 in this embodiment.

A shallow helical groove is shown in FIG. 10 and is machined on the outer surface of the rotor shaft 210 or outer surface of the spacer sleeves. A left-hand helical groove 1010 wraps in a left-hand direction beginning at the center of the space between adjacent rotor plates 120 to one end of the anti-wrap oversleeve 100, and a right-hand helical groove 1020 wraps in the right-hand direction from the center of the same space to the other end of the oversleeve 100. The direction of the helixes serve to collect dirt, then drive the dirt outboard from the rotor shaft 210 and oversleeve 100 interface.

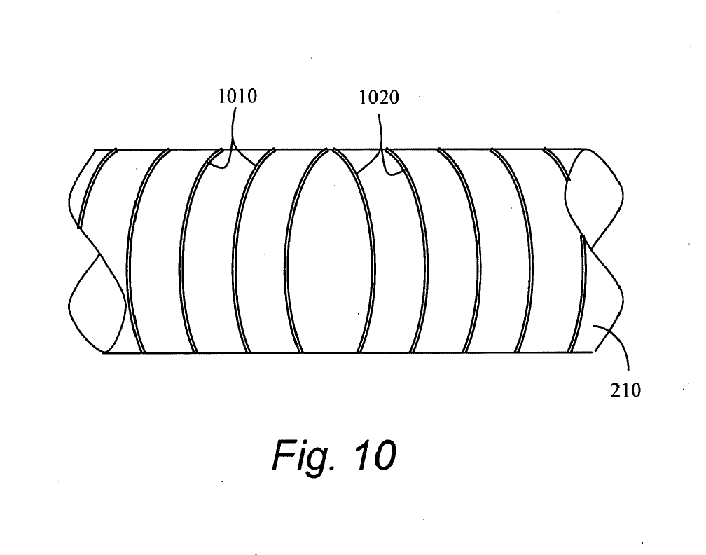

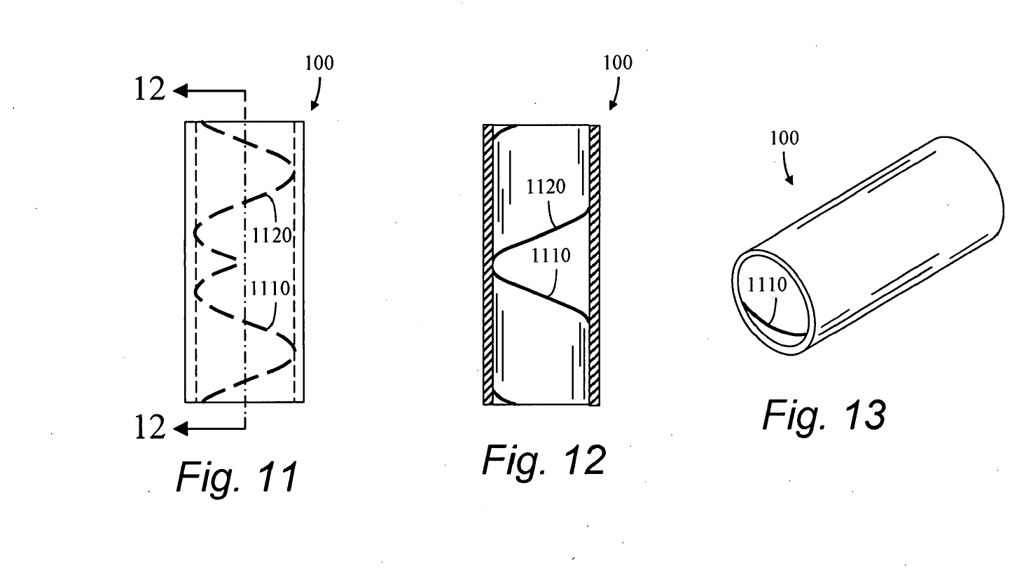

An alternative embodiment to the shallow helical groove 1010, 1020 formed in the outer surface of the rotor shaft 210 shown in FIG. 10 is the shallow helical groove 1110, 1120 formed in the anti-wrap oversleeve 100, as shown in FIGS. 11-13. The anti-wrap oversleeve 100 is in the form of a hollow, right circular cylinder in this case. A left-hand helical groove 1110 wraps in a left-hand direction beginning at the center of the space between adjacent rotor plates 120 to one end of the anti-wrap oversleeve 100, and a right-hand helical groove 1120 wraps in the right-hand direction from the center of the same space to the other end of the oversleeve 100. The direction of the helixes serve to collect dirt, then drive the dirt outboard from the rotor shaft 210 and oversleeve 100 interface.

The above embodiments are the preferred embodiments, but this invention is not limited thereto. It is, therefore, apparent that many modifications and variations of the present invention are possible in light of the above teachings. It is, therefore, to be understood that within the scope of the appended claims, the invention may be practiced otherwise than as specifically described.

We claim:

1. A method of reducing a wrapping of crop material around a rotating implement shaft, the method comprising:
(a) disposing an anti-wrap sleeve about the implement shaft; and
(b) affixing the anti-wrap sleeve to a non-rotating implement component such that the anti-wrap sleeve is substantially stationary relative to the implement shaft.

2. The method of claim 1 wherein the anti-wrap sleeve comprises at least one surface and disposing the anti-wrap sleeve about the implement shaft comprises:
(a) wrapping the anti-wrap sleeve about the implement shaft with the at least one surface adjacent to the implement shaft;
(b) disposing a portion near a first edge of the at least one surface against a first surface of the non-rotating implement component; and
(c) disposing a portion near a second edge of the at least one surface against a second surface of the non-rotating implement component.

3. The method of claim 1 wherein the anti-wrap sleeve comprises at least one surface and affixing the anti-wrap sleeve to the non-rotating implement component comprises:
(a) wrapping the anti-wrap sleeve about the implement shaft with the at least one surface adjacent to the implement shaft;
(b) disposing a first portion near a first edge of the at least one surface against a first surface of the non-rotating implement component;
(c) disposing a second portion near a second edge of the at least one surface against a second surface of the non-rotating implement component; and
(d) operatively fastening the anti-wrap sleeve to the non-rotating implement component where the first portion and second portion of the anti-wrap sleeve are operatively disposed against the non-rotating implement component.

4. The method of claim 1 wherein the implement shaft comprises a rotor shaft and a plurality of rotor plates are operatively affixed to the rotor shaft and spaced a distance apart on said rotor shaft; and wherein disposing the anti-wrap sleeve about the implement shaft comprises disposing the anti-wrap sleeve about the implement shaft between two of the plurality of rotor plates.

5. The method of claim 1 additionally comprising:
(a) installing said implement shaft on an agricultural implement;
(b) bearing said agricultural implement on a ground;
(c) raising the implement shaft relative to the ground;
(d) raising the anti-wrap sleeve simultaneously with the implement shaft such that the anti-wrap sleeve is stationary relative to a longitudinal axis of the implement shaft.

6. The method of claim 1 additionally comprising:
(a) installing said implement shaft on an agricultural implement;
(b) bearing said agricultural implement on ground engaging wheels;
(c) rotating said ground engaging wheels about an axle;
(d) actuating the implement shaft forward relative to the axle;
(e) moving the anti-wrap sleeve simultaneously with the implement shaft such that the anti-wrap sleeve is stationary relative to a longitudinal axis of the implement shaft.

7. The method of claim 1 additionally comprising forming a helical groove in a surface of the implement shaft.

8. The method of claim 7 wherein the helical groove comprises a first helical groove, the method additionally comprising:
(a) orienting the first helical groove in a left handed orientation;
(b) beginning said first helical groove at a center of a segment of the implement shaft;
(c) ending said first helical groove at a first end of the segment of the implement shaft;
(d) forming a second helical groove in the surface of the implement shaft, said second helical groove being right handed;
(e) beginning said second helical groove at the center of the segment of the implement shaft; and
(f) ending said second helical groove at a second end of the segment of the implement shaft.

9. The method of claim 8 wherein the segment of the implement shaft is disposed between two rotor plates, said rotor plates being operatively rigidly affixed to the implement shaft and spaced a distance apart.

10. An apparatus for reducing a wrapping of crop material around a rotating implement shaft, the apparatus comprising:
(a) an anti-wrap sleeve disposed about the implement shaft;
(b) a non-rotating implement component; and
(c) a fastener to operatively fasten the anti-wrap sleeve to the non-rotating implement component.

11. The apparatus of claim 10 wherein the anti-wrap sleeve comprises:
(a) at least one surface wherein said at least one surface is disposed adjacent to the implement shaft;
(b) a first portion of the at least one surface disposed against a first surface of the non-rotating implement component; and
(c) a second portion of the at least one surface disposed against a second surface of the non-rotating implement component.

12. The apparatus of claim 10 wherein the rotating implement shaft comprises a rotor shaft, the apparatus additionally comprising two rotor plates operatively, rigidly affixed to the rotor shaft wherein the anti-wrap sleeve is disposed between the two rotor plates.

13. The apparatus of claim 10 additionally comprising a plurality of rotor plates spaced apart on the implement shaft.

14. The apparatus of claim 10 wherein the anti-wrap sleeve is made of a composite material.

15. The apparatus of claim 10 wherein the non-rotating implement component comprises a stripper pan.

16. The apparatus of claim 10 additionally comprising:
(a) a first helical groove formed in a surface of the implement shaft, said first helical groove being left handed, begun at a center of a segment of the implement shaft, and ended at a first end of the segment of the implement shaft; and
(b) a second helical groove in the surface of the implement shaft, said second helical groove being right handed, begun at the center of the segment of the implement shaft and ended at a second end of the segment of the implement shaft.

17. The apparatus of claim 10 additionally comprising a rod windguard comprising a plurality of rods, wherein said rods are disposed beneath the implement shaft.

18. The apparatus of claim 13 additionally comprising a rod windguard comprising a plurality of rods, wherein said rods are disposed beneath the implement shaft.

19. The method of claim 1 additionally comprising forming a helical groove in an inner surface of the antiwrap sleeve.

20. The method of claim 19 wherein the helical groove comprises a first helical groove, the method additionally comprising:
(a) orienting the first helical groove in a left handed orientation;
(b) beginning said first helical groove at a longitudinal center of the antiwrap sleeve;
(c) ending said first helical groove at a first end of the antiwrap sleeve;
(d) forming a second helical groove in the inner surface of the antiwrap sleeve, said second helical groove being right handed;
(e) beginning said second helical groove at the longitudinal center of the antiwrap sleeve; and
(f) ending said second helical groove at a second end of the antiwrap sleeve.

21. The apparatus of claim 10 additionally comprising:
(a) a first helical groove formed in an inner surface of the anti-wrap sleeve, said first helical groove being left handed, begun at a longitudinal center of the anti-wrap sleeve, and ended at a first end of the anti-wrap sleeve; and
(b) a second helical groove in the inner surface of the anti-wrap sleeve, said second helical groove being right handed, begun at the longitudinal center of the anti-wrap sleeve and ended at a second end of the anti-wrap sleeve.
